(19) United States
(12) Patent Application Publication
(10) Pub. No.: US 2009/0068569 A1
(43) Pub. Date: Mar. 12, 2009

(54) Resin composition for hologram recording material, hologram recording material, and method for producing hologram recording medium

(75) Inventors: Tsutomu Seta, Tokyo (JP); Koji Shirai, Tokyo (JP)

Correspondence Address: WENDEROTH, LIND & PONACK, L.L.P., 2033 K STREET N. W., SUITE 800, WASHINGTON, DC, 20006-1021, US

(73) Assignee: NIPPON PAINT CO., LTD.

(21) Appl. No.: 12/230,838

(22) Filed: Sep. 5, 2008

(30) Foreign Application Priority Data
Sep. 6, 2007 (JP) 2007-231724

(51) Int. Cl. G03F 7/004

(52) U.S. Cl. 430/2

(57) ABSTRACT

The sensitivity, diffraction efficiency, etc. of hologram recording materials is improved. Disclosed is a resin composition for a hologram recording material, the resin composition comprising: a photosensitive component comprising (a) a monomer having a vinyloxy group, (b) a compound having a (meth)acryloxy group, and (c) a photopolymerization initiator; and a prepolymer component, wherein the component (a) is designed so as to be relatively higher or lower in refractive index than the prepolymer component.

### BACKGROUND OF THE INVENTION

1. Field of the Invention

The present invention relates to resin compositions for a hologram recording material, a hologram recording material, and a method to provide hologram recording media, etc.

The “hologram recording medium” as used herein is an item or product to be used for recording holograms. The “hologram recording material” as used herein is a photosensitive material to be used for recording holograms. A hologram recording medium has a hologram recording material which has been shaped appropriately. The “resin composition for hologram recording materials” as used herein is a formless resin composition to be used for forming hologram recording materials.

2. Description of the Related Art

Holographic recording is a recording system in which digital information is two-dimensionalized to form a series of page data and several series of such page data are piled to be recorded as a hologram. It is theoretically possible to achieve a large capacity as large as 1 terabytes by transforming the information to be recorded into interference patterns and recording the interference patterns in the thickness (depth) direction of a record layer.

As hologram recording materials, photosensitive materials of bleached silver salt and dichromated gelatin types have been generally used. However, such photosensitive materials all have problems in that the method for producing photosensitive plates and treatment for producing holograms are complicated, that the holograms produced are poor in environmental resistance, e.g. moisture resistance and weather resistance, and that there is a limitation in resolution. In order to solve such problems, hologram recording materials using photopolymers have been proposed.

One example of hologram recording materials using photopolymers is a material utilizing a combination of a lower refractive polymer matrix and a higher refractive monomer which can be dispersed easily in the polymer in order to form a refractive index modulation pattern by hologram exposure.

During writing of information into the material, by allowing recording light to pass through in an arrangement of displaying data, polymerization of the monomers takes place in regions under the exposure. Due to decrease in monomer concentration caused by the polymerization, the monomers in non-exposed dark regions of the material diffuse to the exposed regions. The polymerization and the concentration gradient caused thereby generate a change in the refractive index of the recording material and, as a result, a hologram which displays data is formed.

Japanese Patent Laid-open Publication No. H11(1999)-352303 discloses a hologram recording material using polyurethane, mercaptan-epoxy, polyether, etc. as a lower refractive polymer matrix and phenyl acrylate, styrene, vinylnaphthalene, etc. as a higher refractive monomer.

However, the prepolymer forming the polymer matrix is so highly reactive that reactions thereof proceed even at room temperature. Therefore, the resin composition for hologram recording materials is poor in storage stability. In addition, it is difficult to reduce the viscosity by heating and is poor in shapability as well.

On the other hand, acrylate monomers are so highly viscous that they can diffuse in a polymer slowly. Vinyl monomers are so less reactive and that the polymerization thereof proceeds slowly. Therefore, this hologram recording material has only an insufficient sensitivity.

Japanese Patent Laid-open Publication No. 2005-275389 discloses a hologram recording material using a Michael addition polymer, etc. as a lower refractive polymer matrix and a fluorene having a (meth)acryloxy group, etc. as a higher refractive monomer. The Michael addition reaction proceeds slowly and is easy to control. In addition, the crosslinking density of the polymer matrix can be optimized easily in conformity with the characteristics of the monomers. Therefore, this hologram recording material is high in sensitivity and brightness and is excellent in recording retention. Moreover, the hologram recording material is also characterized in its easy formability because of the low viscosity of the composition.

However, hologram recording materials are still required for further improvement in sensitivity and diffraction efficiency for the purpose of further increase in capacity and recording speed of hologram recording media.

### SUMMARY OF THE INVENTION

### Problems to be Solved by the Invention

The present invention intends to solve the aforementioned existing problems and the object thereof is to improve the sensitivity and the diffraction efficiency of hologram recording materials.

### Means for Solving the Problem

The present invention provides a resin composition for hologram recording materials, the resin composition comprising
a photosensitive component comprising
(a) a monomer having a vinyloxy group,
(b) a compound having a (meth)acryloxy group, and
(c) a photopolymerization initiator, and
a prepolymer component,
   wherein the component (a) is designed so as to be relatively higher or lower in a refractive index than the prepolymer component.

The present invention provides a hologram recording material comprising
a photosensitive component comprising
(a) a monomer having a vinyloxy group,
(b) a compound having a (meth)acryloxy group, and
(c) a photopolymerization initiator, and
a polymer matrix,
   wherein the component (a) is designed so as to be relatively higher or lower in refractive index than the polymer matrix.

The present invention provides a method for producing a hologram recording medium comprising a step of shaping one of the resin compositions for hologram recording materials into a layer form, and a step of forming a polymer matrix by causing the prepolymer component contained in the resin composition to react.

Number of the functional group contained in the components (a) to (f), such as a vinyloxy group and a (meth)acryloxy group is not limited to one in the molecule.

### Effect of the Invention

According to the present invention, the properties, namely sensitivity and diffraction efficiency, of hologram recording materials are improved and increase in capacity and recording speed of hologram recording media is achieved.

### BRIEF DESCRIPTION OF THE DRAWINGS

FIG. 1 is a schematic diagram illustrating an example of the constitution of an exposure device for evaluating a hologram recording medium. In FIG. 1, L1 is a 650 nm laser, L2 is a 405 nm laser, S1 to S3 are shutters, M1 to M5 are mirrors, O1 is an objective lens, O2 is a collimating lens, O3 and O5 are half-wave plates, O4 is a polarization beam splitter, H is a sample holder, D1 and D2 are light intensity measuring apparatuses.

### BEST MODE FOR CARRYING OUT THE INVENTION

### Photosensitive Component

Component (a) is a monomer having a vinyloxy group. It is necessary to make difference between the refractive index of the component (a) and that of the polymer matrix of the hologram recording material. Therefore, the component (a) is designed so as to be relatively higher or lower in a refractive index than the polymer matrix or a prepolymer for forming the polymer matrix. The method of designing the molecular structures and compositions of the photosensitive component and the polymer matrix so that a difference would occur between the refractive indexes of these materials is known in the art.

The component (a) is a monomer. The refractive index of the component can be changed by appropriately selecting as the monomer a compound having a molecular structure or molecular skeleton which yields a desired refractive index. The refractive index of the prepolymer or polymer matrix is changed by providing a predetermined amount of high refractive structures or low refractive structures in the molecule. The refractive indexes of the propolymer component and the polymer matrix may be calculated also from the refractive indexes of the monomers constituting these materials.

Examples of the structures or skeletons, which yield a high refractive index, include structures having an aromatic ring such as benzene, naphthalene, anthracene and fluorene and structures having a heterocyclic ring such as pyrrole, furan, thiophene and pyridine. Such rings may have a substituent. Conjugated structures and structures having an element such as chlorine, bromine and sulfur also yield high refractive indexes.

Examples of the structure or skeleton which produces a low refractive index include aliphatic chains having no conjugated structure and polyether chains.

While the number of vinyloxy groups is not particularly limited, there are 1 to 6 vinyloxy groups, and preferably there are 1 to 4 vinyloxy groups in one molecule. An excessively large number of vinyloxy groups causes large volume shrinkage during hologram recording and, therefore, it becomes difficult to maintain recorded information.

Specific examples of the component (a) include 4-vinyletherstyrene, hydroquinone divinyl ether, phenyl vinyl ether, bisphenol A divinyl ether, tetrabromobisphenol A divinyl ether, bisphenol F divinyl ether, tetrabromobisphenol F divinyl ether, phenoxyethylenevinyl ether, p-bromophenoxyethylenevinyl ether, and 2-carbazoyl vinyl ether. Moreover, vinyl esters disclosed in J. V. Crivello, D. A. Conlon, “Journal of Polymer Science, Polymer Chemistry Edition,” Vol. 22, page 1789 (1983) are also favorably used.

A preferable component (a) is a vinyl ether monomer having a fluorene skeleton or a vinyl ether monomer having a bisphenol skeleton.

Specific examples of the vinyl ether monomer having a fluorene skeleton include 9,9-bis(4-vinyloxyphenyl)fluorene, 9,9-bis(4-vinyloxymethoxyphenyl)fluorene, 9,9-bis(4-(2-vinyloxyethoxy)phenyl)fluorene, 9,9-bis(4-(2-vinyloxypropoxy)phenyl)fluorene, 9,9-bis(4-(3-vinyloxypropoxy)phenyl)fluorene, 9,9-bis(4-vinyloxydimethoxyphenyl)fluorene, 9,9-bis(4-vinyloxydiethoxyphenyl)fluorene, 9,9-bis(4-vinyloxydipropoxyphenyl)fluorene, 9,9-bis(4-vinyloxytrimethoxyphenyl)fluorene, 9,9-bis(4-vinyloxytriethoxyphenyl)fluorene, 9,9-bis(4-vinyloxytripropoxyphenyl)fluorene, 9,9-bis(4-vinyloxytetramethoxyphenyl)fluorene, 9,9-bis(4-vinyloxytetraethoxyphenyl)fluorene, 9,9-bis(4-vinyloxytetrapropoxyphenyl)fluorene, 9,9-bis(4-vinyloxy-3-methyl phenyl)fluorene, 9,9-bis(4-vinyloxymethoxy-3-methylphenyl)fluorene, 9,9-bis(4-(2-vinyloxyethoxy)-3-methylphenyl)fluorene, 9,9-bis(4-(2-vinyloxypropoxy)-3-methylphenyl)fluorene, 9,9-bis(4-(3-vinyloxypropoxy)-3-methylphenyl)fluorene, 9,9-bis(4-vinyloxydimethoxy-3-methylphenyl)fluorene, 9,9-bis(4-vinyloxydiethoxy-3-methylphenyl)fluorene, 9,9-bis(4-vinyloxydipropoxy-3-methylphenyl)fluorene, 9,9-bis(4-vinyloxytrimethoxy-3-methylphenyl)fluorene, 9,9-bis(4-vinyloxytriethoxy-3-methylphenyl)fluorene, 9,9-bis(4-vinyloxytripropoxy-3-methylphenyl)fluorene, 9,9-bis(4-vinyloxytetramethoxy-3-methylphenyl)fluorene, 9,9-bis(4-vinyloxytetraethoxy-3-methylphenyl)fluorene, 9,9-bis(4-vinyloxytetrapropoxy-3-methylphenyl)fluorene, 9,9-bis(4-vinyloxy-3-ethylphenyl)fluorene, 9,9-bis(4-vinyloxymethoxy-3-ethylphenyl)fluorene, 9,9-bis(4-(2-vinyloxyethoxy)-3-ethylphenyl)fluorene, 9,9-bis(4-(2-vinyloxypropoxy)-3-ethylphenyl)fluorene, 9,9-bis(4-(3-vinyloxypropoxy)-3-ethylphenyl)fluorene, 9,9-bis(4-vinyloxydimethoxy-3-ethylphenyl)fluorene, 9,9-bis(4-vinyloxydiethoxy-3-ethylphenyl)fluorene, 9,9-bis(4-vinyloxydipropoxy-3-ethylphenyl)fluorene, 9,9-bis(4-vinyloxytrimethoxy-3-ethylphenyl)fluorene, 9,9-bis(4-vinyloxytriethoxy-3-ethylphenyl)fluorene, 9,9-bis(4-vinyloxytripropoxy-3-ethylphenyl)fluorene, 9,9-bis(4-vinyloxytetramethoxy-3-ethylphenyl)fluorene, 9,9-bis(4-vinyloxytetraethoxy-3-ethylphenyl)fluorene, 9,9-bis(4-vinyloxytetrapropoxy-3-ethylphenyl)fluorene, 9,9-bis(4-vinyloxy-3-propylphenyl)fluorene, 9,9-bis(4-vinyloxy-3-propylphenyl)fluorene, 9,9-bis(4-(2-vinyloxyethoxy)-3-propylphenyl)fluorene, 9,9-bis(4-(2-vinyloxypropoxy)-3-propylphenyl)fluorene, 9,9-bis(4-(3-vinyloxypropoxy)-3-propylphenyl)fluorene, 9,9-bis(4-vinyloxyoimethoxy-3-propylphenyl)fluorene, 9,9-bis(4-vinyloxydiethoxy-3-propylphenyl)fluorene, 9,9-bis(4-vinyloxydipropoxy-3-propylphenyl)fluorene, 9,9-bis(4-vinyloxytrimethoxy-3-propylphenyl)fluorene, 9,9-bis(4-vinyloxytriethoxy-3-propylphenyl)fluorene, 9,9-bis(4-vinyloxytripropoxy-3-propylphenyl)fluorene, 9,9-bis(4-vinyloxytetramethoxy-3-propylphenyl)fluorene, 9,9-bis(4-vinyloxytetraethoxy-3-propylphenyl)fluorene, 9,9-bis(4-vinyloxytetrapropoxy-3-propylphenyl)fluorene, 9,9-bis(4-vinyloxy-(2-hydroxy)propoxyphenyl)fluorene, 9,9-bis(4-vinyloxy-(2-hydroxy)propoxy-3-methylphenyl)fluorene, and 9,9-bis(4-vinyloxy-(2-hydroxy)propoxyethoxyphenyl)fluorene.

Specific examples of the vinyl ether monomer having a bisphenol skeleton include 2,2-bis(4-vinyloxyethoxyphenyl)propane, bis(4-vinyloxydiethoxyphenyl)methane, bis(4-vinyloxyethoxy-3,5-dibromophenyl)methane, 2,2-bis(4-vinyloxyethoxyphenyl)propane, 2,2-bis(4-vinyloxydiethoxyphenyl)propane, 2,2-bis(4-vinyloxyethoxy-3,5-dibromophenyl)propane, bis(4-vinyloxyethoxyphenyl)sulfone, bis(4-vinyloxydiethoxyphenyl)sulfone, bis(4-vinyloxypropoxyphenyl)sulfone, and bis(4-vinyloxyethoxy-3,5-dibromophenyl)sulfone.

Component (b) is a compound having an acryloxy group (CH₂═CHC(═O)O—) or a methacryloxy group (CH₂═CCH₃C(═O)O—). The reactivity of the monomer having a vinyloxy group is increased by the use of a compound having a (meth)acryloxy group as a photosensitive component. In a preferable embodiment, the reactivity of the monomer having a vinyloxy group has increased to a degree as high as that of a (meth)acrylic monomer.

When a vinyl ether monomer and a (meth)acrylic monomer which are analogous in structure are compared, the former has a lower viscosity than the latter. For this reason, a vinyl ether monomer easily moves in a polymer and therefore it easily causes concentration distribution due to its polymerization. Such a characteristic is useful for a photosensitive component of hologram recording materials and can contribute to increase in the sensitivity and recording speed of hologram recording materials.

However, a vinyl ether monomer has a problem in that the reactivity thereof is lower than that of (meth)acrylic monomers. In other words, the polymerization proceeds slowly in exposed portions. Therefore, use of a vinyl ether monomer as a photosensitive component have heretofore resulted in delay in fixation of interference patterns and also has led to reduction in the sensitivity and recording speed of hologram recording materials.

The inventors of the present invention found that use of a (meth)acrylic compound such as (meth)acrylic monomers in combination with a vinyl ether monomer greatly improves the reactivity of the vinyl ether monomer. This finding made it possible to accelerate the progress of the polymerization while making use of high mobility of the vinyl ether monomer. In other words, the use of a (meth)acrylic compound and a vinyl ether monomer in combination as the photosensitive of a hologram recording material has made it possible to increase in the sensitivity and recording speed of hologram recording materials, which was impossible by use of a (meth)acrylic monomer alone or a vinyl ether monomer alone.

The amount of the component (b) used is an amount such that the molar ratio of the (meth)acryloxy groups of the component (b) to the vinyloxy groups of the component (a) is from 1/100 to 400/100, and preferably from 1/100 to 200/100. If the ratio is less than 1/100, the reactivity of the vinyl monomer is improved insufficiently. If the ratio is over 400/100, the mobility of the monomer components becomes insufficient.

The component (b) may be a monomer, an oligomer, or a polymer. Specific examples of the component (b) include methyl acrylate, ethyl acrylate, n-butyl acrylate, isobutyl acrylate, t-butyl acrylate, 2-ethylhexyl acrylate, lauryl acrylate, stearyl acrylate, cyclohexyl acrylate, hydroxyethyl acrylate, hydroxypropyl acrylate, hydroxybutyl acrylate, glycidyl acrylate, N-acryloylmorpholine, 2-ethylhexylcarbitol acrylate, isobornyl acrylate, methoxypropylene glycol acrylate, 1,6-hexanediol diacrylate, tetraethylene glycol diacrylate, trimethylolpropane triacrylate, pentaerythritol triacrylate, pentaerythritol tetraacrylate, acrylamide, methacrylamide, styrene, 2-bromostyrene, phenyl acrylate, 2-pheoxyethyl acrylate, (acryloxyethyl) 2,3-naphthalene dicarboxylate monoester, methylphenoxyethyl acrylate, nonylphenoxyethyl acrylate, β-acryloxyethyl hydrogen phthalate, phenoxy polyethylene glycol acrylate, 2,4,6-tribromophenyl acrylate, (2-methacryloxyethyl) diphenate monoester, benzyl acrylate, 2,3-dibromopropyl acrylate, 2-hydroxy-3-phenoxypropyl acrylate, 2-naphthyl acrylate, N-vinylcarbazole, 2-(9-carbazolyl)ethyl acrylate, triphenylmethyl thioacrylate, 2-(tricyclo[5,2,10^{2.6}]dibromodecylthio)ethyl acrylate, S-(1-naphthylmethyl) thioacrylate, dicyclopentanyl acrylate, methylene bisacrylamide, polyethylene glycol diacrylate, trimethyrolpropane triacrylate, pentaerythritol triacrylate, (2-acryloxyethyl) (3-acryloxypropyl-2-hydroxy) diphenate diester, (2-acryloxyethyl) (3-acryloxypropyl-2-hydroxy) 2,3-naphthalenedicarboxylate diester, (2-acryloxyethyl) (3-acryloxypropyl-2-hydroxy) 4,5-phenanthrenedicarboxylate diester, dibromoneopenthyl glycol diacrylate, dipentaerythritol hexaacrylate, 1,3-bis-[2-acryloxy-3-(2,4,6-tribromophenoxy)propoxy]benzene, diethylene dithioglycol diacrylate, 2,2-bis(4-acryloxyethoxyphenyl)propane, bis(4-acryloxydiethoxyphenyl)methane, bis(4-acryloxyethoxy-3,5-dibromophenyl)methane, 2,2-bis(4-acryloxyethoxyphenyl)propane, 2,2-bis(4-acryloxydiethoxyphenyl)propane, 2,2-bis(4-acryloxyethoxy-3,5-dibromophenyl)propane, bis(4-acryloxyethoxyphenyl)sulfone, bis(4-acryloxydiethoxyphenyl)sulfone, bis(4-acryloxypropoxyphenyl)sulfone, bis(4-acryloxyethoxy-3,5-dibromophenyl)sulfone, compounds wherein the above-described acrylate is changed to methacrylate, and ethylenically unsaturated double bond-containing compounds having at least two S atoms in a molecule as described in Japanese Patent Laid-open Publication Nos. H2(1990)-247205 or H2(1990)-261808.

The component (b) may also be a (meth)acrylic monomer having a fluorene skeleton. Specific examples of such a (meth)acrylic monomer include 9,9-bis(4-acryloxydiethoxyphenyl)fluorene (BPFA) and monomers having structures produced by changing each of the vinyloxy groups in the structures of the vinyl ether monomers having a fluorene skeleton provided as examples of the component (a) to a (meth)acryloxy group.

Esters of aliphatic polyhydric alcohols or their ethylene oxide- or propylene oxide-adducts with (meth)acrylic acid also can be used as the component (b). Examples thereof are ethylene glycol di(meth)acrylate, diethylene glycol di(meth)acrylate, triethylene glycol di(meth)acrylate, tetraethylene glycol di(meth)acrylate, propylene glycol di(meth)acrylate, dipropylene glycol di(meth)acrylate, tripropylene glycol di(meth)acrylate, tetrapropylene glycol di(meth)acrylate, 1,3-butylene glycol di(meth)acrylate, trimethylolpropane tri(meth)acrylate, 1,4-butanediol di(meth)acrylate, neopentyl glycol di(meth)acrylate, 1,6-hexanediol di(meth)acrylate, pentaerythritol di(meth)acrylate, pentaerythritol tri(meth)acrylate, pentaerythritol tetra(meth)acrylate, glycerol di(meth)acrylate, tricyclodecane dimethanol di(meth)acrylate, and dipentaerythritol poly(meth)acrylate. A compound the same as the component (e), which is described later, may be used as the component (b).

Component (c) is a photopolymerization initiator. A photopolymerization initiator has a role of initiating the photopolymerization between the components (a) and (b) by irradiation with a laser beam or light with excellent coherence which has a specific wavelength in an interference pattern exposure process.

The amount of the component (c) to be used is determined depending on the kind thereof in consideration of the amounts of the functional groups contained in the components (a) and (b), the concentration in the resin composition for hologram recording materials, etc. In general, the component (c) is used in an amount such that the concentration of the component (c) contained in a resin composition for hologram recording materials would become from 0.05 to 20% by mass in solid content.

Examples of photopolymerization initiators which can be used include, but are not limited to, known initiators described in U.S. Pat. Nos. 4,766,055, 4,868,092, 4,965,171, Japanese Patent Laid-open Publication Nos. S54(1979)-151204, S58(1983)-15503, S58(1983)-29803, S59(1984)-189340, S60(1985)-76735, H1(1989)-287105, Japanese Patent Application No. H3(1991)-5569, Proceedings of Conference on Radiation Curing Asia, pages 461-477 (1988), etc.

Specific examples of the photopolymerization initiator include diaryl iodonium salts disclosed in Japanese Patent Laid-open Publication Nos. S58(1983)-29803 and H1(1989)-287105 and Japanese Patent Application No. H3(1991)-5569, or 2,4,6-substituted-1,3,5-triazines (triazine-based compounds) and titanocene compounds. Specific examples of the diaryl iodonium salts include chloride, bromide, tetrafluoroborate, hexafluorophosphate, hexafluoroaresenate, hexafluoroantimonate, trifluoromethanesulfonate and 9,10-dimethoxyanthracene-2-sulfonate of diphenyl iodonium, 4,4′-dichlorodiphenyl iodonium, 4,4′-dimethoxydipehyl iodonium, 4,4′-di-tert-butyldiphenyl iodonium and 3,3′-dinitrodiphenyl iodonium. Further, specific examples of the 2,4,6-substituted-1,3,5-triazines include 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2,4-bis(trichloromethyl)-6-(p-methoxyphenylvinyl)-1,3,5-triazine, and 2-(4′-methoxy-1′-naphthyl)-4,6-bis(trichloromethyl)-1,3,5-triazine. Specific examples of the titanocene compounds include bis(cyclopentadienyl)dichlorotitanium, bis(cyclopentadienyl)diphenyltitanium, bis(cyclopentadienyl)-bis (2,3,4,5,6-pentafluorophenyl)titanium, bis(cyclopentadienyl)-bis(2,6-difluorophenyl)titanium, bis(methylcyclopentadienyl)-bis(2,3,4,5,6-pentafluorophenyl)titanium, bis(methylcyclopentadienyl)-bis(2,6-difluorophenyl)titanium, bis(cyclopentadienyl)-bis[2,6-difluoro-3-(2-(1-pyrr-1-yl)ethyl)phenyl]titanium, bis(cyclopentadienyl)-bis[2,6-difluoro-3-((1-pyrr-1-yl)methyl)phenyl]titanium, bis(methylcyclopentadienyl)-bis[2,6-difluoro-3-((1-pyrr-1-yl)methyl)phenyl]-titanium, bis(cyclopentadienyl)-bis[2,6-difluoro-3-((2,5-dimethyl-1-pyrr-1-yl)methyl)-phenyl]titanium, bis(cyclopentadienyl)-bis[2,6-difluoro-3-((3-trimethylsilyl-2,5-dimethyl-1-pyrr-1-yl)methyl)phenyl]titanium, bis(cyclopentadienyl)-bis[2,6-difluoro-3-((2,5-bis(morpholinomethyl)-1-pyrr-1-yl)methyl)phenyl]titanium, bis(cyclopentadienyl)-bis[2,6-difluoro-4-((2,5-dimethyl-1-pyrr-1-yl)methyl)-phenyl]titanium, bis(cyclopentadienyl)-bis[2,6-difluoro-3-methyl-4-(2-(1-pyrr-1-yl)ethyl)-phenyl]titanium, bis(cyclopentadienyl)-bis[2,6-difluoro-3-(1-methyl-2-(1-pyrr-1-yl)ethyl)-phenyl]titanium, bis(cyclopentadienyl)-bis[2,6-difluoro-3-(6-(9-carbazol-9-yl)hexyl)-phenyl]titanium, bis(cyclopentadienyl)-bis[2,6-difluoro-3-(3-(4,5,6,7-tetrahydro-2-methyl-1-indol-1-yl)propyl)phenyl]titanium, bis(cyclopentadienyl)-bis[2,6-difluoro-3-((acetylamino)methyl)phenyl]-titanium, bis(cyclopentadienyl)-bis[2,6-difluoro-3-(2-(propionylamino)ethyl)phenyl]-titanium, bis(cyclopentadienyl)-bis[2,6-difluoro-3-(4-(pivaloylamino)butyl)phenyl]-titanium, bis(cyclopentadienyl)-bis[2,6-difluoro-3-(2-(2,2-dimethylpentanoylamino)-ethyl)phenyl]titanium, bis(cyclopentadienyl)-bis[2,6-difluoro-3-(3-(benzoylamino)propyl)phenyl]-titanium, bis(cyclopentadienyl)-bis[2,6-difluoro-3-(2-(N-allylmethylsulfonylamino)-ethyl)phenyl]titanium, and bis(cyclopentadienyl)-bis(2,6-difluoro-3-(1-pyrr-1-yl)phenyl)titanium. Other examples are α-aminoalkyl ketones and acylphosphine oxides. Specific examples of the α-aminoalkyl ketones include 2-(4-methylbenzyl)-2-dimethylamino-1-(4-morpholinophenyl)butanone-1and 2-benzyl-2-dimethylamino-1-(4-morpholinophenyl)butanone-1. An example of the acylphosphine oxides is bis(2,6-dimethoxybenzoyl)-2,4,4-trimethylpentylphosphine oxide.

### Prepolymer Component

A prepolymer is a precursor of a polymer. A prepolymer is a resin composition having fluidity and it undergoes a polymerization reaction to form a polymer matrix. The prepolymer component has a relative difference in refractive index by comparison with a monomer having a vinyloxy group, which is the component (a). It is preferable that the difference in refractive index is larger because the difference in refractive index from the photosensitive becomes large, and the diffraction efficiency of a hologram recording material is improved.

The kind of the prepolymer component is not particularly restricted. For example, any prepolymer capable of forming a polymer matrix by utilizing a polymerization reaction such as those shown below can be used. Examples of the polymerization reaction include epoxy-amine step polymerization, unsaturated ester-amine step polymerization (by Michael addition), isocyanate-hydroxyl step polymerization (urethane formation), isocyanate-amine step polymerization (urea formation), and step polymerization by nucleophilic addition (Michael addition reaction) to a Michael acceptor with a carboanion.

A preferable prepolymer is one which contains (d) a compound having an active methylene group or a compound having two or more active methine groups, (e) a compound having two or more groups to which a carboanion which generates from an active methylene group or an active methine group is capable of being nucleophilically added, (f) a Michael reaction catalyst as constituents.

Such a prepolymer component generally has a low viscosity and reacts slowly. Therefore, it is easy to shape the hologram recording material and, moreover, the crosslinking density of the polymer matrix can be optimized easily in conformity with the property of monomers. Depending upon the design of feeding amounts of the components (a) and (d), and (e), it is possible to introduce the same structure to both a matrix component and a polymer component which is formed in recording interference patterns. This results in improvement in compatibility of the matrix component and the polymer component of the interference patterns and reduces noises contained in the recorded information.

Component (d) is a compound having an active methylene group or a compound having two or more active methine groups.

The active methylene group or active methine group is a methylene group or methine group which has a high acidity and forms a carboanion easily. In general, a methylene group or methine group situated between electron withdrawing groups has a high acidity and is active.

An example of the component (d) is a product of reaction between an alcohol and a carboxylic acid containing an active methylene group and/or an active methine group and/or a derivative thereof. Examples of the derivative of a carboxylic acid containing an active methylene group and/or an active methine group include carboxylic acid esters and carboxylic acid anhydrides. Specific examples of the carboxylic acid containing an active methylene group and derivatives thereof include acetoacetic acid, malonic acid, cyanoacetic acid, and derivatives such as esters thereof. Specific examples of the carboxylic acid containing an active methine group and derivatives thereof include methane tricarboxylic acid and derivatives such as esters thereof, as those disclosed in EP publication No. 0310011

The active methylene group is preferably a methylene group situated between two carbonyl groups which is in the state where it is with excessive electrons due to the carbonyl groups and it is easy to release protons to generate carboanions. The active methine group is preferably a methine group situated between three carbonyl groups which is in the state where it is with excessive electrons due to the carbonyl groups and it is easy to release protons to generate carboanions.

The alcohol which reacts with the carboxylic acid containing an active methylene group and/or an active methine group may be either a monoalcohol or a polyhydric alcohol.

Examples of the monoalcohol include methanol, ethanol, propanol and butanol. Examples of the polyhydric alcohol include compounds having two or more hydroxyl groups in a molecule, such as ethylene glycol, diethylene glycol, propylene glycol, tetramethylene glycol, 1,6-henanediol, neopentyl glycol, trimethylolpropane, glycerin, pentaerythritol, 1,4-cyclohexanedimethanol, 4,4′-isopropylidenedicyclohexanol, bis(hydroxymethyl)tricyclo[5,2,1,0]decane, 1,3,5-tris(2-hydroxyethyl)cyanuric acid, and isopropylidenebis(3,4-cyclohexanediol).

Examples of the component (d) include products of reaction between a polyfunctional amine compound and a diketene. Examples of the polyfunctional amine compound include compounds having two or more amino groups in a molecule, such as ethylenediamine, 1,3-diaminopropane, 1,4-diaminobutane, 1,6-hexanediamine, 1,12-diaminododecane, 1,2-diaminocyclohexane, phenylenediamine, piperazine, 2,6-diaminotoluene, diethyltoluenediamine, N,N′-bis(2-aminopropyl)ethylenediamine, and N,N′-bis(3-aminopropyl)-1,3-propanediamine.

On the other hand, examples of the compound (d) include products of reaction between an isocyanate compound and a carboxylic acid containing an active methylene group and/or an active methine group and/or its derivative. Specific examples of the isocyanate compound include hexamethylene diisocyanate, lysine diisocyanate, 4,4′-methylenebis(cyclohexylisocyanate), methylcyclohexane diisocyanate, 1,3-(isocyanatomethyl)cyclohexane, isophorone diisocyanate, trimethylhexamethylene diisocyanate, norbornene diisocyanate, and dimmers, trimmers and adducts of such isocyanates.

The component (d) may be a polymeric compound. When the component (d) is a polymeric compound, it is provided an advantage that the hologram recording materials may easily be designed in their properties as desired by designing the polymeric compound. Specific examples of the polymeric compound include a polymer or a copolymer of ethylenically unsaturated monomers which comprise at least an ethylenically unsaturated monomer containing an active methylene group and/or an active methine group.

Specific examples of the ethylenically unsaturated monomers containing an active methylene group and/or an active methine group include acetoacetoxyethyl (meth)acrylate, ethyl-2-(meth)acryloxyoxyethyl malonate, and the like. Ethylenically unsaturated monomers optionally to be copolymerized with the ethylenically unsaturated monomers, are not particularly limited to, unless they contain an active methylene group and/or an active methine group. Specific examples thereof include the mono(meth)acrylates described as the component (b) such as methyl (meth)acrylate and ethyl (meth)acrylate.

The polymer or the copolymer may be synthesized by conventional methods such as a radical polymerization method using monomer solution, and the molecular weight is, for example, adjusted about from 1000 to 100000, preferably about from 2000 to 50000 in number average. If the number average molecular weight of the polymer or the copolymer is less than 1000, the advantage for the polymeric compound becomes hard to occur. If it is more than 100000, the hologram recording materials may have high viscosity to be difficult in handling.

When the polymer or the copolymer is that containing an active methylene group, concentration contained in solid of the active methylene group is from 0.1 to 7 mmol/g, preferably 0.3 to 4 mmol/g. When the polymer or the copolymer is that containing an active methine group, concentration contained in solid of the active methine group is from 0.2 to 7 mmol/g, preferably 0.6 to 5 mmol/g. If concentration of the active methylene group and/or the active methine group is less than the lower limits, the resin composition insufficiently cures to weaken mechanical strength of the hologram recording material. If concentration of the active methylene group and/or the active methine group is more than the upper limits, the hologram recording material may become excessively hard, or shrinkage on curing apt to occur.

If the component (d) is a compound having a methylene group, crosslinking can be caused by only one methylene group because an active methylene group has two active hydrogens and the active hydrogens can react with two molecules of the component (e).

In the present invention, it is possible to obtain a significant effect by causing the component (e) to undergo nucleophilic addition by use of a compound containing one or more active methylene groups in one molecule or a component (d) containing two or more active methine groups in one molecule.

The component (e) is a compound having two or more groups to which a carboanion which generates from an active methylene group or an active methine group is capable of being nucleophilically added. Such a compound is required only to be a so-called Michael acceptor, examples of which include compounds having two or more (meth)acryloxy groups.

Specific examples of the component (e) include the compounds having two or more (meth)acryloxy groups among the compounds listed as the specific examples of the component (b). Among these compounds, preferred as a lower refractive component are esters of an aliphatic polyhydric alcohol or its ethylene oxide- or propylene oxide-adduct with a (meth)acrylic acid. Preferred as a higher refractive component are di(meth)acrylates having a fluorene skeleton and di(meth)acrylates having a bisphenol skeleton.

The amount of the component (e) used is an amount such that the molar ratio of the groups to which carboanions be nucleophilically added (e.g. (meth)acryloxy groups) of the component (e) to the active methylene groups and/or active methine groups of the component (d) becomes from 0.1/1 to 10/1, and preferably from 0.2/1 to 5/1. If the ratio is smaller than 0.1/1 or if the ratio is over 10/1, a sufficient solid form may fail to be imparted.

Component (f) is a Michael reaction catalyst. A Michael reaction catalyst is a compound necessary for generating carboanion (enolate anion) by increasing the acidity of methylene (methine) proton by electron withdrawing groups such as two carbonyl groups adjacent to methylene (methine).

The amount of the component (f) to be used is determined depending on a kind thereof in consideration of amounts of functional groups contained in the components (d) and (e) and a concentration in the resin composition for hologram recording materials. In general, the component (f) is used in an amount such that the concentration of the component (f) contained in a resin composition for hologram recording materials would become from 0.1 to 5% by mass in solid content.

Examples of the Michael reaction catalyst include alkali metal hydroxides, such as sodium hydroxide and potassium hydroxide; alkali metal alkoxides, such as sodium methoxide and potassium ethoxide; onium salts, such as quaternary ammonium halides, quaternary ammonium carbonates, quaternary ammonium hydroxides and quaternary ammonium tetrahydroborates; tertiary amines, such as tetramethylguanidine, 1,8-diazabicyclo[5,4,0]undecene-7 and diazabicyclo[4,3,0]nonene-5; guanidine; amidine; and tertiary phosphines, such as triphenylphosphine. Moreover, as co-catalysts for such Michael reaction catalysts, epoxy compounds which have been made known to the public by Japanese Patent Laid-open Publication No. H7(1995)-173262, such as glycidyl (meth)acrylate, can be used.

Specific examples of the cationic portion of the onium salt include quaternary ammonium cations such as tetrabutylammonium cation, tetramethylammonium cation, tetrapropylammonium cation, tetrahexylammonium cation, tetraoctylammonium cation, tetradecylammonium cation, tetrahexadecylammonium cation, triethylhexylammonium cation, 2-hydroxylethyltrimethylammonium (choline) cation, methyltrioctylammonium cation, cetyltrimethylammonium cation, 2-chloroetyltrimethylammonium cation and methylpyridniumammonium cation; quaternary phosphonium cations such as tetrabutylphosphonium cation; and tertiary sulfonium cations such as trimethylsulfonium cation. Quaternary ammonium cations, various types of which are industrially available, are preferred.

Specific examples of the anionic portion of the onium salt include halide anions such as fluoride anion, chloride anion, bromide anion and iodide anion; carboxylate anions such as acetic acid anion, benzoic acid anion, salicylic acid anion, maleic acid anion and phthalic acid anion; sulfonate anions such as methanesulfonic acid anion, p-toluenesulfonic acid anion and dodecylbenzenesulfonic acid anion; sulfate anions such as sulfuric acid anion and metosulfuric acid anion; nitrate anions such as nitric acid anion; and phosphate anions such as phosphoric acid anion and di-tert-butyl phosphoric acid anion. In addition, hydroxide anion, carbonate anion and tetrahydroborate anion can also be provided as examples. In view of curability, halide anions and carboxylate anions are preferred.

Examples of the onium salts include tetrabutylammonium chloride, tetrabutylammonium fluoride, tetraethylammonium bromide, diethyldibutylammonium chloride, octyltrimethylammonium bromide, tetrabutylammonium acetate, dioctyldimethylammonium salicylate, benzyllauryldimethylammonium chloride, 2-hydroxyethyltrimethylammonium chloride, tetraethylphosphonium chloride, tetraethylphosphonium bromide, tetrabutylphosphonium chloride, and trimethylsulfonium chloride.

As the components (a) through (f), the compounds provided as examples may be used alone or as a combination of two or more of them.

### Resin Composition for Hologram Recording Materials

The resin composition for hologram recording materials of the present invention may be prepared by an ordinary method. For example, it can be prepared by mixing the aforementioned photosensitive component and prepolymer component as it is or with a solvent optionally incorporated, in a cool, dark place by use of a high speed stirrer. The mixing ratio of the photosensitive component and the prepolymer component, in solid mass ratio, is generally from 10/90 to 70/30, and preferably from 20/80 to 60/40. If the solid mass ratio is less than 10/90 or more than 70/30, sufficient diffraction efficiency may fail to be obtained.

Examples of the solvent which can be used in the mixing include ketone solvents, such as methyl ethyl ketone, acetone and cyclohexanone; ester solvents, such as ethyl acetate, butyl acetate and ethylene glycol diacetate; aromatic solvents, such as toluene and xylene; cellosolve® solvents, such as methyl cellosolve®, ethyl cellosolve® and butyl cellosolve®; alcohol solvents, such as methanol, ethanol and propanol; ether solvents, such as tetrahydrofuran and dioxane; and halogen solvents, such as dichloromethane and chloroform. When a solvent is used, the solvent also may also be removed from the resin composition, for example, under reduced pressure in a step prior to the injection processing described later.

In the resin composition for hologram recording materials of the present invention, organic solvents, thermal polymerization inhibitors, silane coupling agents, plasticizers, colorants, leveling agents, defoaming agents, etc. may be incorporated, if necessary.

### Hologram Recording Material and Hologram Recording Medium

Using a resin composition for hologram recording materials of the present invention prepared in the method as described above, a hologram recording material and a hologram recording medium can be produced.

First, a resin composition for hologram recording materials is shaped. The shape into which the resin composition is to be formed may be any shape suited to the portion of a desired hologram recording medium where interference patterns are to be recorded. In general, it is preferable to shape the resin composition into a layer form. The thickness of the layer is, for example, from 5 to 2000 μm, and preferably from 200 to 1500 μm.

If the thickness is excessively small, it is impossible to obtain a sufficient recording capacity. Conversely, if it is excessively thick, the permeability of light is affected and therefore it becomes difficult to record information. Moreover, a large curing shrinkage will occur in hologram recording and therefore the recording retention of information may be affected.

The shaping can be performed by any method conventionally known for shaping photopolymers for hologram recording. One example of a preferable shaping method is described in paragraphs 0073 to 0081 of Japanese Patent Laid-open Publication No. 2005-275389.

Then, the prepolymer component in the shaped resin composition layer is caused to react. The reaction of the prepolymer component is performed usually by heating. By heating, the component (d) reacts in nucleophilic addition to the component (e) to polymerize. At this time, while the component (d) can react in nucleophilic addition also to the component (a), the addition reaction between the component (d) and the component (e) preferentially proceed because the component (e) has a higher Michael addition reactivity. By this reaction, a polymer matrix is formed in the resin composition layer and a solid form is imparted thereto. A compound resulting from a reaction of part of the functional groups of the component (e) with the component (d) may be generated, such a compound functions as a component (b). The component (a) which reacted with the prepolymer or the component (e) which remains unreacted will function to improve the compatibility of the prepolymer component with a polymer component which will be generated in interference pattern recording.

In an actual reaction of forming a polymer matrix, not all functional groups react because the fluidity of components is lost during the reaction. Therefore, unreacted (meth)acryloxy groups will remain in the polymer matrix. The (meth)acryloxy groups remained in the polymer matrix, as a result, functions as a component (b) of a hologram recording material.

If so, the amount of the (meth)acryloxy groups which function as a component (b) contained in the hologram recording material does not necessarily agree with an amount theoretically calculated on the basis of the charged amount of the components (b), (d) and (e), and therefore measurement is required in order to determine that amount precisely. One example of the method of such measurement is described as an Example.

In this hologram recording material, the abundance ratio of the (meth)acryloxy groups (all (meth)acryloxy groups capable of serving as component (b)) to the vinyloxy groups of the component (a), in a molar ratio, is preferably from 1/100 to 100/100, and more preferably from 1/100 to 50/100. If the ratio is less than 1/100, the reactivity of the vinyl ether monomer is improved insufficiently. If the ratio is over 100/100, the mobility of the monomer components becomes insufficient due to increase in viscosity of the photosensitive component.

As a result of the above-described operations, a hologram recording material and a hologram recording medium are formed. The resulting hologram recording material has a polymer matrix composed mainly of the component (d) and the component (e) and the photosensitive component contains the component (a) as a primary ingredient. Therefore, it is possible to enhance the diffraction efficiency by increasing the relative difference in refractive index between the component (a) and the components (d) and (e).

Such an embodiment include an example in which the component (a) has a structure or skeleton which provides a high refractive index and the components (d) and (e) fail to have such structure or skeleton and an example in which the component (a) fails to have a structure or skeleton which provides a high refractive index and the component (d) and (e) have such a structure or skeleton.

### Hologram

On exposure of a laser light or a light having excellent coherence having a specific wavelength (e.g. a light having a wavelength of 400 to 700 nm) to the hologram recording material, interference patterns are recorded inside the recording layer due to the polymerizing of the photosensitive component. In the present invention, in this stage, a refraction light by the interference patterns recorded is obtained to provide a hologram.

The methods of the present invention may further comprise a post-exposure process of polymerizing uncured compounds by irradiating the resin composition with a light having low coherence after the interference pattern exposure process. Specifically, it is possible to polymerize the unreacted components by irradiation with a light to which the photopolymerization initiator contained in the composition is sensitive (for example, a light having a wavelength of 200 to 600 nm). In addition, the refraction efficiency, the peak wavelength of refraction light, the half width, etc. may be changed by treating a recording layer with heat or infrared light before post exposure.

### EXAMPLES

The following examples further illustrate the present invention concretely, but the invention is not limited thereto. Unless stated otherwise, “part” represents part by mass.

### Production Example 1

Production of Higher Refractive Monomer (V-1) having a Vinyloxy Group

Into a reaction vessel equipped with a stirrer, a temperature controller and a condenser, 100 parts of 20% aqueous solution of sodium hydroxide was charged and the temperature thereof was kept at 35° C. Subsequently, 11.0 parts of 9,9-bis-[4-(2-hydroxyethoxy)phenyl]fluorene, 10.7 parts of 2-chloroethyl vinyl ether and 0.170 parts of tetra-n-butylammonium hydrogensulfate were added and stirred for 12 hours while keeping the temperature at 35° C. The oil phase of the product was extracted with diethyl ether, dried over sodium sulfate, and then concentrated with a rotary evaporator. Thus, 9,9-bis[4-vinyloxydiethoxyphenyl]fluorene was obtained.

### Production Example 2

Production of Higher Refractive Monomer (V-2) having a Vinyloxy Group

2,2-Bis[4-vinyloxydiethoxyphenyl]propane was obtained in the same manner as Production Example 1 except for using 6.46 parts of 2,2-bis[4-(2-hydroxyethoxy)phenyl]propane instead of 9,9-bis-[4-(2-hydroxyethoxy)phenyl]fluorene.

### Production Example 3

Production of Active Methylene Group-Containing Compound (M-1)

Into a reaction vessel, 135 parts of methyl acetoacetate and 35 parts of trimethylolpropane were charged and heated to 145° C. over 1 hour while introducing N₂. Then, stirring was continued at 145° C. for 1 hour while removing methanol with a decanter, and it was confirmed that almost the theoretical amount of methanol had been recovered. Thereafter, unreacted methyl acetoacetate was distilled off at 155° C. under reduced pressure to yield a desired compound. The number of the active methylene groups contained in one molecule was measured to be 3.7 functional groups (theoretically 4 groups).

### Production Example 4

Production of Active Methylene Group-Containing Compound (M-2)

Into a reaction vessel equipped with a nitrogen introducing tube, a stirrer, a temperature controller and a condenser, 42.4 parts of methyl isobutyl ketone was charged, and the temperature was raised to 115° C. Nitrogen was put through the system. After the temperature became stable, a mixture solution of 26.6 parts of acetoacetoxyethyl methacrylate and 23.2 parts of methyl methacrylate, and a mixture solution of 0.249 parts of t-butyl peroxy-2-ethylhexanoate and 3.44 parts of methyl isobutyl ketone were simultaneously dropwise added to the contents at constant rate for 3 hours. Heat generated from the system is appropriately removed to maintain the temperature at 115° C. After the dropwise addition, stirring was continued for 30 minutes while the temperature was kept at 115° C., and a mixture solution of 0.149 parts of t-butyl peroxy-2-ethylhexanoate and 3.98 parts of methyl isobutyl keton was dropwise added to the contents at constant rate for 30 minutes. Stirring was further continued for 2 hours while the temperature was kept at 115° C. to obtain a solution of active methylene group-containing acrylic resin which has a solid content of 50% and an active methylene group concentration in solid of 2.5 mmol/g.

### Example 1

Preparation of Resin Composition for Hologram Recording Materials

First, 149 parts of the (M-1) produced in Production Example 3, 180 parts of tripropylene glycol diacrylate, 289 parts of the (V-1) produced in Production Example 1, 5.32 parts of photopolymerization initiator “IRGACURE 784” produced by Ciba Specialty Chemicals Inc., 3.02 parts of tetrabutylammonium fluoride, 14.2 parts of glycidyl methacrylate, and 500 parts of acetone were mixed and stirred until the solids dissolved. Then, acetone was distilled off under reduced pressure, thereby obtaining a resin composition for hologram recording materials.

Production of Hologram Recording Medium

An evaluation test panel was produced by sandwiching the resin composition between two glass substrates each having an antireflection coating on one side via 500 μm-thick resin spacers with the antireflection coated sides faced outwardly.

Pre-Reaction

A hologram recording material was obtained by heating the test plate at 60° C. for 9 hours to cause the photosensitive composition to undergo a pre-reaction.

Measurement of the abundance ratio of (meth)acryloxy groups to vinyloxy groups

The compositions before and after the heating were measured for IR spectrum. Then, on the basis of the peak height changes of the absorption due to acryloxy groups (found at 1407 cm⁻¹) and the absorption due to vinyloxy groups (found at 1319 cm⁻¹), the reaction ratios of both the types of functional groups in the pre-reaction were calculated. Then, by the use of the reaction ratios and the charged molar numbers of the acryloxy groups and the vinyloxy groups, the abundance ratio (X) of the acryloxy groups to the vinyloxy groups in the hologram recording material was calculated according to the following formula. The value of X was 14.

$$X = \frac{\begin{matrix}( Reaction ratio of acryloxy groups in pre \text{-} reaction ) \times \\ ( Charged molar number of acryloxy groups )\end{matrix}}{\begin{matrix}( Reaction ratio of vinyloxy groups in pre \text{-} reaction ) \times \\ ( Charged molar number of vinyloxy groups )\end{matrix}} \times 100$$

Evaluation of Hologram Characteristics

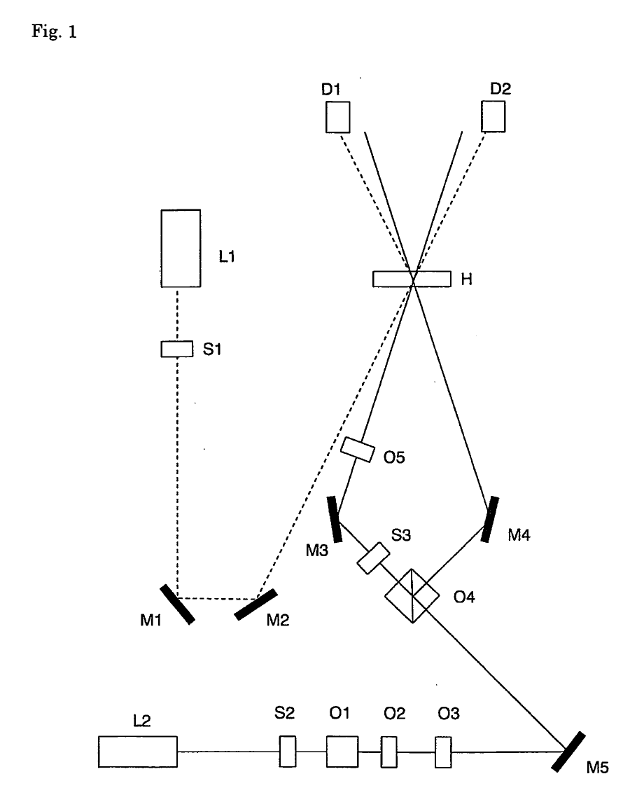

FIG. 1 is a schematic view illustrating an example of the constitution of an exposure device for evaluating a hologram recording material. The exposure device is composed of a 405 nm laser for recording, a 650 nm laser for reading, and a plurality of optical parts.

The characteristics evaluation of hologram recording materials were conducted by using the evaluation apparatus constituted as shown in FIG. 1. A hologram recording material was placed at point H in FIG. 1 and 405 nm laser beams which had been enlarged and collimated through O1 and O2 was applied from two directions so that they could intersect each other at H. The intensity of the laser beams for recording is 2.4 mW/cm². The interference patterns formed at the intersection are recorded on the hologram recording material.

At the same time, the intersection of the recording laser beams was irradiated with a 650 nm laser beam at an appropriate angle. The changes with time in the intensity of the transmitted light detected at D2 and the intensity of the diffracted light detected at D1 were measured. The laser beam for evaluation is diffracted by the interference patterns recorded in the material by the laser for recording.

Since the hologram recording material produced in this Example is not sensitive to a 650 nm light, it is possible to trace the course of interference pattern formation caused by a 405 nm laser. The diffraction efficiency is calculated by the formula:

{light intensity of D1/(light intensity of D1+light intensity of D2)}×100,

and the irradiated energy is calculated by multiplying the intensity of the laser for recording by the irradiation time. Therefore, data of the change in the diffraction efficiency with respect to the irradiated energy can be obtained by these evaluation operations.

The diffraction efficiency shows its maximum value at a certain irradiated energy. The hologram recording characteristics were evaluated using the values of the irradiation energy and the diffraction efficiency when the maximum value was shown first. The irradiated energy at the maximum serves as a measure for evaluating the sensitivity and the value of the diffraction efficiency serves as a measure for evaluating the performance of recording information. The smaller the irradiation energy at the maximum, the higher the sensitivity is. The higher the diffraction efficiency, the higher the performance of record information is. The values obtained in these evaluations are shown in Table 1.

### Example 2

A hologram recording material was prepared in the same manner as Example 1 except for using 136 parts of compound (V-2) instead of the compound (V-1). Then, the hologram characteristics were evaluated. The results are listed in Table 1.

### Example 3

First, 84.1 parts of hexamethylene diisocyanate, 95.0 parts of polypropylene glycol having a molecular weight of 200, 2.24 parts of trimethylol propane, 4.70 parts of tripropylene glycol diacrylate, 181 parts of the (V-1) produced in Production Example 1, 2.99 parts of photopolymerization initiator “IRGACURE 784” produced by Ciba Specialty Chemicals Inc., 1.69 parts of tetrabutylammonium fluoride, 7.96 parts of glycidyl methacrylate, 0.184 parts of dibutyltin dilaurate, and 367 parts of acetone were mixed and stirred until the solids dissolved. Then, acetone was distilled off under reduced pressure, thereby obtaining a resin composition for hologram recording. Subsequent operations were carried out as in Example 1. The results are shown in Table 1.

### Example 4

First, 149 parts of the (M-1) produced in Production Example 3, 85.7 parts of 9,9-bis[4-acryloxydiethoxyphenyl]fluorene, 231 parts of the (V-1) produced in Production Example 1, 3.79 parts of photopolymerization initiator “IRGACURE 784” produced by Ciba Specialty Chemicals Inc., 2.15 parts of tetrabutylammonium fluoride, 10.1 parts of glycidyl methacrylate, and 465 parts of acetone were mixed and stirred until the solids dissolved. Then, acetone was distilled off under reduced pressure, thereby obtaining a resin composition for hologram recording materials. Subsequent operations were carried out in the same manner as in Example 1. The results are shown in Table 1. The value of X was 1.1.

### Example 5

First, 37.1 parts of the (M-1) produced in Production Example 3, 200 parts of 9,9-bis[4-acryloxydiethoxyphenyl]fluorene, 90.4 parts of the (V-1) produced in Production Example 1, 2.67 parts of photopolymerization initiator “IRGACURE 784” produced by Ciba Specialty Chemicals Inc., 1.51 parts of tetrabutylammonium fluoride, 7.11 parts of glycidyl methacrylate, and 328 parts of acetone were mixed and stirred until the solids dissolved. Then, acetone was distilled off under reduced pressure, thereby obtaining a resin composition for hologram recording materials. Subsequent operations were carried out in the same manner as in Example 1. The results are shown in Table 1. The value of X was 98.

### Example 6

First, 37.1 parts of the (M-1) produced in Production Example 3, 123 parts of dipentaerythritol hexaacrylate, 261 parts of the (V-1) produced in Production Example 1, 3.43 parts of photopolymerization initiator “IRGACURE 784” produced by Ciba Specialty Chemicals Inc., 1.94 parts of tetrabutylammonium fluoride, 9.14 parts of glycidyl methacrylate, and 421 parts of acetone were mixed and stirred until the solids dissolved. Then, acetone was distilled off under reduced pressure, thereby obtaining a resin composition for hologram recording materials. Subsequent operations were carried out in the same manner as in Example 1. The results are shown in Table 1. The value of X was 95.

### Example 7

First, 200 parts of the (M-4) produced in Production Example 4, 45.0 parts of tripropylene glycol diacrylate, 129 parts of the (V-1) produced in Production Example 1, 2.36 parts of photopolymerization initiator “IRGACURE 784” produced by Ciba Specialty Chemicals Inc., 1.33 parts of tetrabutylammonium fluoride, and 6.28 parts of glycidyl methacrylate were mixed and stirred until the solids dissolved. Then, methyl isobutyl ketone was distilled off under reduced pressure, thereby obtaining a resin composition for hologram recording materials. Subsequent operations were carried out in the same manner as in Example 1. The results are shown in Table 1.

### Comparative Example 1

A hologram recording material was prepared in the same manner as Example 1 except for using 317 parts of 9,9-bis[4-acryloxydiethoxyphenyl]fluorene instead of the compound (V-1). Then, the hologram characteristics were evaluated. The results are listed in Table 1.

### Comparative Example 2

A hologram recording material was prepared in the same manner as Example 1 except for using 163 parts of 2,2-bis[4-acryloxydiethoxyphenyl]propane instead of the compound (V-1). Then, the hologram characteristics were evaluated. The results are listed in Table 1.

### Comparative Example 3

A hologram recording material was prepared in the same manner as Example 3 except for using 199 parts of 9,9-bis[4-acryloxydiethoxyphenyl]fluorene instead of the compound (V-1). Then, the hologram characteristics were evaluated. The results are listed in Table 1.

### Comparative Example 4

First, 149 parts of the (M-1) produced in Production Example 3, 31.7 parts of 9,9-bis[4-acryloxydiethoxyphenyl]fluorene, 350 parts of the (V-1) produced in Production Example 1, 4.31 parts of photopolymerization initiator “IRGACURE 784” produced by Ciba Specialty Chemicals Inc., 2.45 parts of tetrabutylammonium fluoride, 11.5 parts of glycidyl methacrylate, and 530 parts of acetone were mixed and stirred until the solids dissolved. Then, acetone was distilled off under reduced pressure, thereby obtaining a resin composition for hologram recording materials. Subsequent operations were carried out in the same manner as in Example 1. The results are shown in Table 1. The value of X was 0.12.

### Comparative Example 5

First, 37.1 parts of the (M-1) produced in Production Example 3, 259 parts of 9,9-bis[4-acryloxydiethoxyphenyl]fluorene, 65.1 parts of the (V-1) produced in Production Example 1, 2.94 parts of photopolymerization initiator “IRGACURE 784” produced by Ciba Specialty Chemicals Inc., 1.66 parts of tetrabutylammonium fluoride, 7.83 parts of glycidyl methacrylate, and 361 parts of acetone were mixed and stirred until the solids dissolved. Then, acetone was distilled off under reduced pressure, thereby obtaining a resin composition for hologram recording materials. Subsequent operations were carried out in the same manner as in Example 1. The results are shown in Table 1. The value of X was 230.

TABLE 1

| | Irradiated energy at the | Diffraction | |
|---|---|---|---|
| | maximum value (mJ/cm²) | efficiency (%) | X |
| Example 1 | 28 | 50 | 14 |
| Example 2 | 25 | 11 | — |
| Example 3 | 55 | 45 | — |
| Example 4 | 48 | 38 | 1.1 |
| Example 5 | 43 | 32 | 98 |
| Example 6 | 21 | 25 | 95 |
| Example 7 | 39 | 41 | — |
| Comparative | 102 | 5 | — |
| Example 1 | | | |
| Comparative | 94 | 3 | — |
| Example 2 | | | |
| Comparative | 110 | 13 | — |
| Example 3 | | | |
| Comparative | 130 | 2 | 0.12 |
| Example 4 | | | |
| Comparative | 83 | 3 | 230 |
| Example 5 | | | |

The hologram recording material of the present invention is so highly sensitive that it can reach the maximum diffraction efficiency with irradiated energy less than that needed by the conventional materials. The value of the maximum diffraction efficiency is also larger than conventional and therefore the performance of information recording is also high.

What is claimed is:

1. A resin composition for a hologram recording material, the resin composition comprising
a photosensitive component comprising
(a) a monomer having a vinyloxy group,
(b) a compound having a (meth)acryloxy group, and
(c) a photopolymerization initiator, and
a prepolymer component,
wherein the component (a) is designed so as to be relatively higher or lower in refractive index than the prepolymer component.

2. The resin composition for a hologram recording material according to claim 1, wherein the component (a) is a vinyl ether monomer having a fluorene skeleton or a vinyl ether monomer having a bisphenol skeleton.

3. The resin composition for a hologram recording material according to claim 1, wherein the component (b) is a (meth)acrylic monomer having a fluorene skeleton or esters of aliphatic polyhydric alcohols or their ethylene oxide- or propylene oxide-adducts with (meth)acrylic acid.

4. The resin composition for a hologram recording material, according to claim 1, wherein the prepolymer component comprises
(d) a compound having an active methylene group or a compound having two or more active methine groups,
(e) a compound having two or more groups to which a carboanion which generates from an active methylene group or an active methine group is capable of being nucleophilically added, and
(f) a Michael reaction catalyst, wherein the component (a) is designed so as to be relatively higher or lower in refractive index than the prepolymer component.

5. The resin composition for a hologram recording material according to claim 4, wherein the component (d) is a product of reaction between an alcohol and a carboxylic acid containing an active methylene group and/or an active methine group and/or a derivative thereof, or a polymer or a copolymer of ethylenically unsaturated monomers which comprise at least an ethylenically unsaturated monomer containing an active methylene group and/or an active methine group.

6. The resin composition for a hologram recording material according to claim 4, wherein the component (b) is
a compound the same as the component (e), or
a compound resulting from a reaction of the component (d) with part of the functional groups of the component (e).

7. The resin composition for a hologram recording material according to claim 4, wherein
the component (a) is a vinyl ether monomer having a fluorene skeleton or a vinyl ether monomer having a bisphenol skeleton,
the component (b) is a (meth)acrylic monomer having a fluorene skeleton or esters of aliphatic polyhydric alcohols or their ethylene oxide- or propylene oxide-adducts with (meth)acrylic acid, and
the component (d) is a product of reaction between an alcohol and a carboxylic acid containing an active methylene group and/or an active methine group and/or a derivative thereof, or a polymer or a copolymer of ethylenically unsaturated monomers which comprise at least an ethylenically unsaturated monomer containing an active methylene group and/or an active methine group, and
the component (e) is the same as the component (b).

8. The resin composition for a hologram recording material according to claim 7, wherein the component (a) is selected from the group consisting of 9,9-bis[4-vinyloxydiethoxyphenyl]fluorene and 2,2-bis [4-vinyloxydiethoxyphenyl]propane.

9. The resin composition for a hologram recording material according to claim 7, wherein the component (b) is tripropylene glycol diacrylate.

10. The resin composition for a hologram recording material according to claim 7, wherein the component (d) is a product of reaction between trimethylolpropane and methyl acetoacetate or a copolymer of acetoacetoxyethyl methacrylate and methyl methacrylate.

11. The resin composition for a hologram recording material according to claim 7, wherein molar ratio of the (meth)acryloxy groups of the component (b) to the vinyloxy groups of the component (a) is from 1/100 to 400/100.

12. A hologram recording material comprising
a photosensitive component comprising
(a) a monomer having a vinyloxy group,
(b) a compound having a (meth)acryloxy group, and
(c) a photopolymerization initiator, and
a polymer matrix,
wherein the component (a) is designed so as to be relatively higher or lower in refractive index than the polymer matrix.

13. The hologram recording material according to claim 12, wherein the polymer marix is prepared by causing to react by heating the prepolymer component comprising
(d) a compound having an active methylene group or a compound having two or more active methine groups,
(e) a compound having two or more groups to which a carboanion which generates from an active methylene group or an active methine group is capable of being nucleophilically added, and
(f) a Michael reaction catalyst, wherein the component (a) is designed so as to be relatively higher or lower in refractive index than the prepolymer component.

14. The hologram recording material according to claim 13, wherein
the component (a) is a vinyl ether monomer having a fluorene skeleton or a vinyl ether monomer having a bisphenol skeleton,
the component (b) is a (meth)acrylic monomer having a fluorene skeleton or esters of aliphatic polyhydric alcohols or their ethylene oxide- or propylene oxide-adducts with (meth)acrylic acid, and
the component (d) is a product of reaction between an alcohol and a carboxylic acid containing an active methylene group and/or an active methine group and/or a derivative thereof, or a polymer or a copolymer of ethylenically unsaturated monomers which comprise at least an ethylenically unsaturated monomer containing an active methylene group and/or an active methine group, and
the component (e) is the same as the component (b).

15. The hologram recording material according to claim 12, wherein the abundance molar ratio of the (meth)acryloxy groups to the vinyloxy groups in the hologram recording material is from 1/100 to 100/100.

16. The hologram recording material according to claim 12, wherein the abundance molar ratio of the (meth)acryloxy groups to the vinyloxy groups in the hologram recording material is from 1/100 to 50/100.

17. A method of producing a hologram recording medium comprising a step of shaping the resin composition for hologram recording materials according to claim 1 into a layer form, and a step of forming a polymer matrix by causing the prepolymer component contained in the resin composition to react.

18. A method of producing a hologram recording medium comprising a step of shaping the resin composition for hologram recording materials according to claim 2 into a layer form, and a step of forming a polymer matrix by causing the prepolymer component contained in the resin composition to react.

19. A method of producing a hologram recording medium comprising a step of shaping the resin composition for hologram recording materials according to claim 7 into a layer form, and a step of forming a polymer matrix by causing the prepolymer component contained in the resin composition to react.
